(19) United States
(12) Patent Application Publication
(10) Pub. No.: US 2022/0357778 A1
(43) Pub. Date: Nov. 10, 2022

(54) COMPUTING DEVICES AND MOUNTS ATTACHABLE BY MAGNETIC COUPLING

(71) Applicant: Shopify Inc., Ottawa (CA)

(72) Inventors: David WADDELL, Nelson (CA); Michael Joseph DEFAZIO, Fonthill (CA)

(73) Assignee: Shopify Inc., Ottawa (CA)

(21) Appl. No.: 17/314,116

(22) Filed: May 7, 2021

(51) Int. Cl. G06F 1/18; F16B 1/00; H05K 5/02

(52) U.S. Cl. CPC G06F 1/182; F16B 1/00; H05K 5/0204; F16B 2001/0035

(57) ABSTRACT

A computing device and a device mount. The computing device includes a device casing having a front side and a back side and the device mount has a mount end formed with a mount face sized to fit within a recessed portion of the back side of the device casing in contact with a recessed face of the back side of the device casing. The computing device includes permanent magnets to secure the computing device to the mount face by magnetic coupling between with one or more corresponding magnets in the device mount. One of the recessed face or the mount face is formed from a thermoplastic resin and includes a plurality of raised portions. The raised portions project above the recessed face or the mount face, as the case may be, and have a thickness sufficiently small that the raised portions deform under contact between the mount face and the recessed face due to force of the magnetic coupling.

### FIELD

The present disclosure relates to computing devices and mounts attachable thereto such as by way of magnetic coupling and, in particular, to casings for such devices and/or mounts.

### BACKGROUND

In certain contexts, a handheld computing device may be designed to be detachably/selectively secured to a device mount. The device mount may be a docking station or other customized surface or set of surfaces for supporting the computing device. In some cases, such as in a point-of-sale context or when operating as an information kiosk or the like, the device mount may be a projecting pole with a mount end having a mount face designed to connect to the backside of the computing device. In some implementations, magnetic coupling is used, with or without additional mechanical coupling, to secure the computing device to the device mount.

When a magnetic coupling is used, magnets in the computing device and in the device mount project magnetic fields and couple together to draw the computing device towards the device mount. As will be appreciated, the closer the device comes to the device mount, the stronger the magnetic forces become. At times this can result in a sudden “snapping” or rapid acceleration of the computing device towards the device mount, causing an impact between the casing of the computing device and the mount face of the device mount, which can damage or mar the casing.

### BRIEF DESCRIPTION OF THE DRAWINGS

Embodiments will be described, by way of example only, with reference to the accompanying figures wherein:

FIG. 1 shows a perspective view of an example handheld computing device attached to a device mount;

FIG. 2 shows a perspective view of the backside of one example of the computing device;

FIG. 3 shows a plan view of the backside of the example computing device;

FIG. 4 shows, in perspective view, one example embodiment of the device mount;

FIG. 5 shows a cross-sectional view of one example embodiment of a computing device and a mount end;

FIG. 6 shows a cross-sectional view of another example embodiment of a computing device and a mount end;

FIG. 7 shows a cross-sectional view of a portion of an example casing of a computing device;

FIG. 8 shows a cross-sectional view of a portion of another example of a casing of a computing device;

FIG. 9 shows a cross-sectional view of a portion of a further example of a casing of a computing device;

FIG. 10 shows a cross-sectional view of a portion of yet another example of a casing of a computing device; and

FIG. 11 shows a cross-sectional view of the portion of the casing of FIG. 10 when contacting the mount face of a device mount.

### DETAILED DESCRIPTION

In one aspect, the present application describes a computing device that includes a device casing having a front side and a back side, and one or more permanent magnets within the device casing and proximate the back side to secure the handheld computing device to a mount face of a corresponding device mount by magnetic coupling between the one or more permanent magnets and one or more corresponding magnets in the device mount. The back side of the device casing may include a recessed portion having a recessed face to receive the mount face of the corresponding device mount in contact with the recessed face, and the recessed face may be formed from a thermoplastic resin and includes a plurality of raised portions, the raised portions projecting above the recessed face and having a thickness sufficiently small that the raised portions deform under contact with the mount face due to force of the magnetic coupling.

Conveniently, such a device casing may avoid damage and/or marring from impacts or forces experienced by, or due to, mechanical coupling and/or any such damage and/or marring may be limited.

In some implementations, the computing device may further include a device screen on the front side of the device casing.

In some implementations, the plurality of raised portions form alphanumeric characters or related symbols as at least part of an information label.

In some implementations, the plurality of raised portions are formed from a selected resin and formed to have a height above the recessed face and the thickness to elastically deform under an impact force caused by the magnetic coupling to the mount face. In some cases, the plurality of raised portions return to an original shape after absorbing the impact force.

In some implementations, at least one of the one or more permanent magnets is disposed at least partly below the plurality of raised portions. In some cases, at least one of the one or more permanent magnets is disposed to be directly opposite one of the corresponding magnets in the device mount when the computing device is on the device mount.

In some implementations, the one or more permanent magnets are symmetrically disposed relative to at least a center line of the recessed face. In some cases, the raised portions are symmetrically disposed relative to at least the center line.

In some implementations, the computing device further includes a communications port having a plurality of contact points located within the recessed face for electrical connection to a corresponding communications port within the mount face of the device mount.

In some implementations, the device casing is formed from a first thermoplastic resin and the raised portions are formed from a second thermoplastic resin. The first thermoplastic resin and the second thermoplastic resin are the same in some examples, and are different in some other examples. In some cases, the first thermoplastic resin and the second thermoplastic resin are different in at least one of resin type, additives, or colour. The resin types may include at least one of polycarbonate or polyurethane.

The present application further describes a device mount for a computing device having a device casing with a back side. The device mount may include a mounting arm having a mount end formed with a mount face sized to fit within a recessed portion of the back side of the device casing in contact with a recessed face of the back side of the device casing; and one or more magnets within the mount end proximate the mount face to secure the computing device to the mount face by magnetic coupling with one or more corresponding permanent magnets in the computing device. The mount face may be formed from a thermoplastic resin and includes a plurality of raised portions, the raised portions projecting above the mount face and having a thickness sufficiently small that the raised portions deform under contact with the recessed face due to force of the magnetic coupling.

In some implementations, the mount face is formed from a first thermoplastic resin and the raised portions are formed from a second thermoplastic resin.

In some implementations, the one or more magnets within the mount end are disposed at least partly beneath the plurality of raised portions.

In some implementations, the plurality of raised portions are formed from a selected resin and formed to have a height above the recessed face and the thickness to elastically deform under an impact force caused by the magnetic coupling to the recessed face. In some cases, the plurality of raised portions return to an original shape after absorbing the impact force.

In yet another aspect, the present application describes a system that includes a computing device and a device mount. The computing device in the system may include any one or more of the herein described features of the computing device. The device mount in the system may include any one or more of the herein described features of the device mount.

For illustrative purposes, specific example embodiments will now be explained in greater detail below in conjunction with the figures.

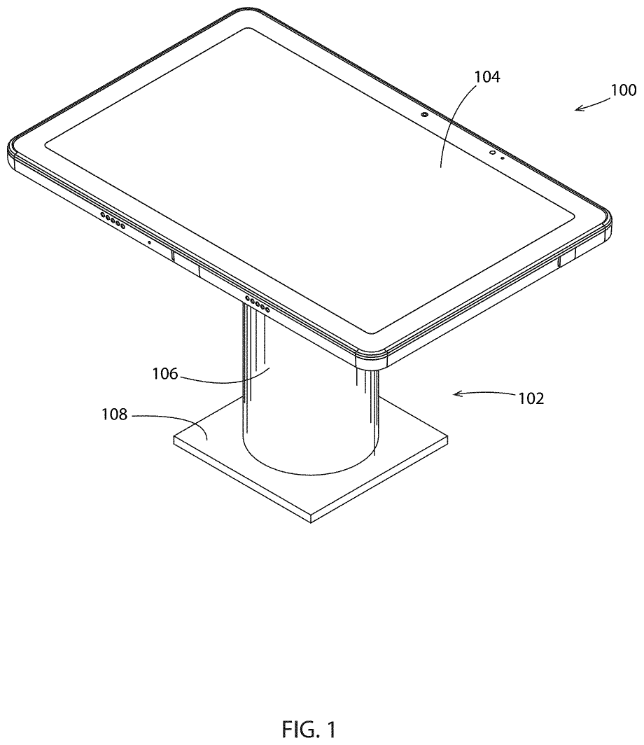

FIG. 1 shows a perspective view of a computing device 100 attached to a device mount 102. The device mount 102 is secured to a backside of the computing device 100 so as to expose the front side of the computing device 100 to users enabling them to view and manipulate a display screen 104.

The device mount 102 in this example includes a mounting pole 106 projecting upwards from a device mount base 108 that may be secured to a counter, table, or other surface. In some cases, the pole 106 and base 108 may be configured for mounting to a vertical or inclined surface. The mounting pole 106 may be configured with hinges or axes or joints that enable tilting or swiveling of the computing device 100 once mounted to the device mount 102. In some instances, the mounting pole 106 may be configured to telescope (not shown) so as to have an adjustable height. A telescoping pole may have a locking mechanisms or sufficient resistance to avoid accidental or unintentional changes in height of the telescoping pole.

The computing device 100 may, in some cases, be a point-of-sale device or other such dedicated-purpose computing device. In some cases, the computing device 100 is a general purpose tablet or other mobile device. In some cases, the general purpose tablet or other mobile device is configured to operate in a kiosk mode in which its available functionality for ordinary non-administrator users is limited to a specific application or applications for its function, such as for point-of-sale or sign-in or menu selection etc.

The computing device 100 in these examples is detachably secured to the device mount 102 and is held in place at least partly by way of a magnetic coupling between the computing device 100 and the device mount 102. In some implementations, the computing device 100 and device mount 102 are designed to be detachably secured to as to enable switching between a “mobile” mode in which the computing device 100 is detached and used while roaming a retail location or other environment, and a “stationary” mode in which the computing device 100 is attached and used as a kiosk or point-of-sale. In some environments and applications the attaching and detaching to switch between mobile and stationary mode may occur with relative frequency.

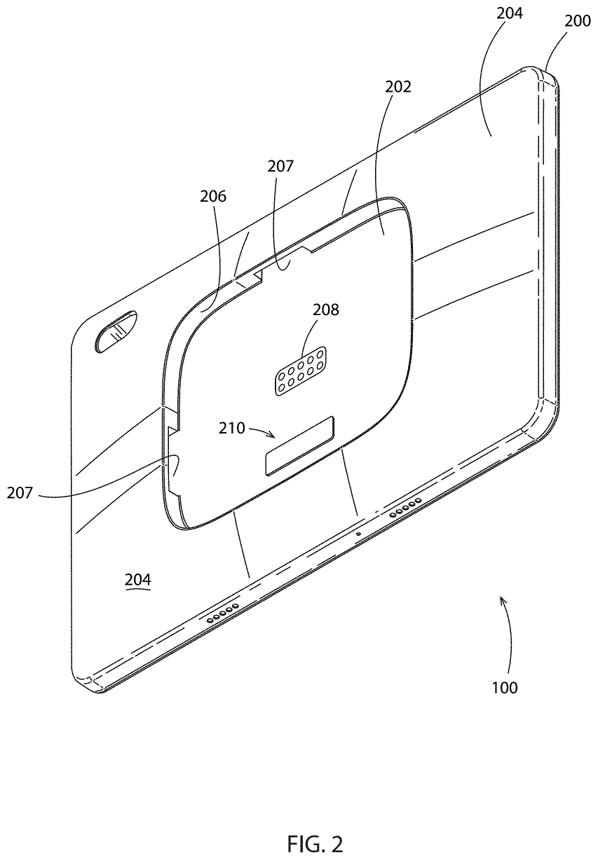

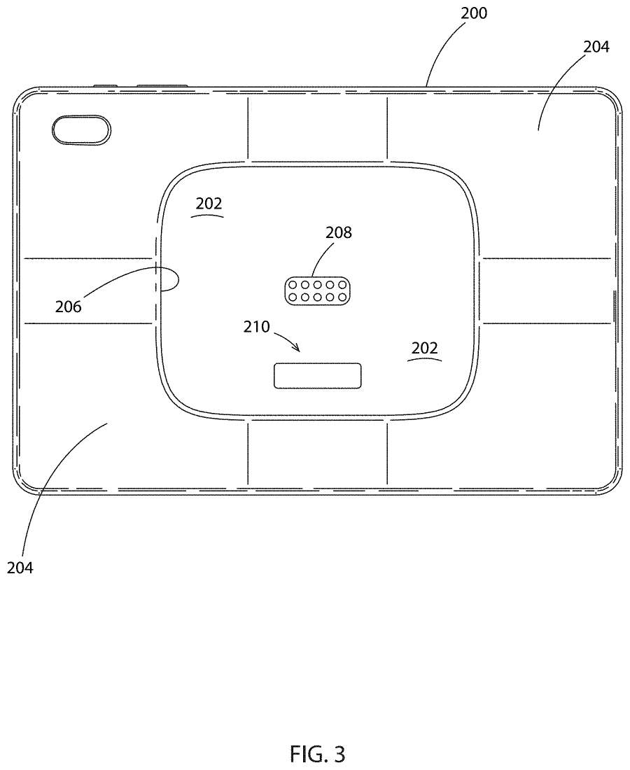

Reference is now made to FIG. 2, which shows a perspective view of the backside of one example of the computing device 100, and FIG. 3, which shows a plan view of the backside of the example computing device 100.

The computing device 100 may include a casing 200 typically formed from a plastic. The casing 200 houses the electronic components of the computing device 100. In these examples, the casing 200 includes a front side within which the display screen 104 (FIG. 1) is located and a back side configured to be attached to the device mount 102 (FIG. 1). In particular, the backside of the casing 200 includes an indentation for receiving a corresponding portion of the device mount 102. As illustrated, the backside of the casing 200 is shaped to have a recessed portion that includes recessed face 202. The recessed portion may be stepped in from a surrounding portion 204 of the casing 200. The depth of the recessed portion may be between 5 mm and 20 mm in some implementations.

In some cases, the recessed portion and its recessed face 202 is partly defined by a recessed sidewall 206 surrounding the recessed face 202. In some implementation, the recessed sidewall 206 includes mechanical latching components for mechanically securing the computing device 100 to the device mount 102. For instance, in some cases the recessed sidewall 206 may include one or more pairs of indentations 207 designed to receive corresponding projections from the device mount 102. The projections may be releasably spring-biased in a locked or extended state and may be sized to engage the indentations 207 when the computing device 100 is attached to the device mount 102.

The casing 200, including the recessed portion and its recessed face 202, is formed from a plastic. The plastic may be molded using injection molding in some cases. The plastic may be formed from one or more thermoplastic resins. The thermoplastic resin may be a polycarbonate plastic in some cases. In another example, the resin may be a thermoplastic polyurethane. Other thermoplastic resins may be used. In some implementations, the casing 200 may be formed from more than one thermoplastic resin.

The recessed portion and, in some examples, the recessed face 202, may include one or more electrical contact points. That is, in some cases, the recessed face 202 features one or more electrical connectors, such as electrical port 208. The electrical port 208 may include one or more electrical contacts. In some cases, the device mount 102 may include one or more corresponding electrical contact points such that when the computing device 100 is mounted to the device mount the respective electrical contact points are electrically connected. In some instances, one or more of the contact points may supply electrical power for charging the computing device 100. In some instances, one or more of the contacts points may enable low-voltage communications connectivity.

In accordance with one aspect of the present application, the recessed face 202 may further include a raised portion 210. The raised portion 210 is raised in the sense that it projects above the plane of the face of the recessed face 202. As will be described further below, the raised portion 210 may be a singular raised portion or a plurality of raised portions. The raised portions may be formed as dimples, ridges, or other shapes. In some cases, the raised portions may be formed to create alphanumeric characters, glyphs, logos or other recognizable symbols.

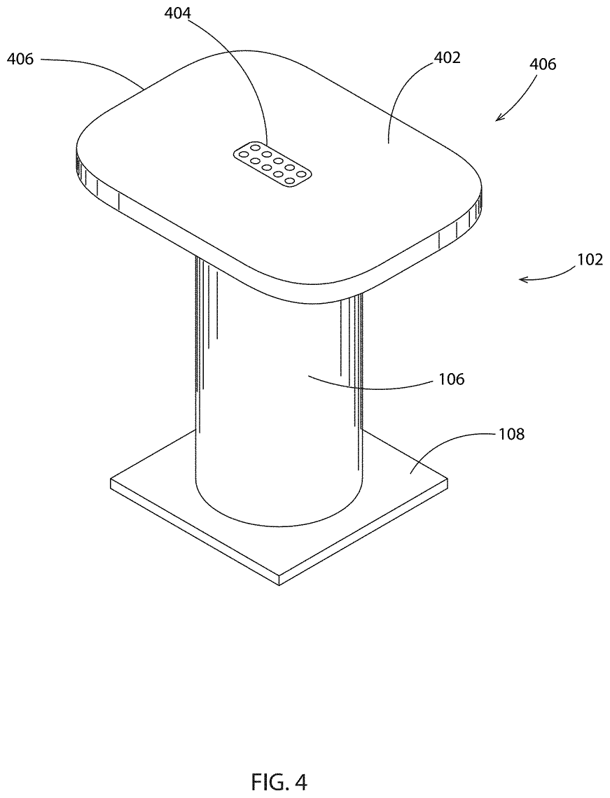

Reference will now be made to FIG. 4, which shows, in perspective view, one example embodiment of the device mount 102. The device mount 102 in this example includes the mounting arm or pole 106 and the mount base 108. The device mount 102 further includes a mount end 400 to which the computing device 100 is to be mounted. The mount end 400 includes a mount face 402 sized to fit within the corresponding recessed portion of the backside of the computing device 100 (FIG. 1). In some embodiments, the mount face 402 may have one or more electrical contacts 404 arranged to contact or couple to corresponding electrical contacts on the computing device 100. The mount face 402 is generally planar and configured to come into flush contact with the corresponding recessed face 202 of the computing device 100 when the computing device 100 is mounted to the device mount 102.

The device mount 102 may be formed from any suitable material and may be wholly or partly formed from plastic. The plastic used may be the same as or different form the plastic used in forming the casing 200 (FIG. 2) of the computing device 200. In some cases, some of the device mount 102 may be constructed from other materials, including metal. It will be appreciated that the mount face 402 may be formed from a non-conductive material, such as a plastic.

Referring still to FIGS. 1 to 4, the computing device 100 is configured to be detachably mounted to the device mount 102. In some instances, the profile of a perimeter 406 of the mount face 402 may be sized to be smaller than the inner recessed sidewall 206 of the recessed portion of the computing device 100. In some instances, the profile of the perimeter 406 of the mount face 402 may be sized to be approximately the same as the inner recessed sidewall 206 of the recessed portion of the computing device 100, but smaller within a certain tolerance to ensure the mount face 402 fits within the recessed portion. In some cases, the profile of the perimeter 406 of the mount face 402 may be sized to friction fit within the inner recessed sidewall 206 of the recessed portion of the computing device 100.

A magnetic coupling is used to secure the computing device 100 to the device mount 102. One or more magnets within the casing 200 of the computing device 100 magnetically couple with one or more magnets within the mount end 400 and, in particular, beneath the surface of the mount face 402 to urge the computing device 100 and mount face 402 toward each other. The one or more magnets within the casing 200 may be positioned behind the recessed face 202. When the computing device 100 and, in particular, the recessed portion of the backside of the casing 200, is brought into close proximity of the mount face 402, the magnetic fields from the magnets behind the recessed face 202 and the mount face 402 couple together and exert a magnetic force to urge the mount face 202 and recessed face 202 together.

As will be appreciated, the closer the magnets become, the stronger the force of attraction becomes, such that over the final millimeters of distance between the recessed face 202 and the mount face 402, the force approaches its maximum and may cause a rapid acceleration of the computing device 100 toward the mount end 400 causing the recessed face 202 to strike the mount face 402 with significant momentum. This is particularly the case where a user holding the computing device 100 loses their grip on the computing device 100 as the magnetic force pulls the computing device 100 from their hands, thereby causing a rapid acceleration of the computing device 100 towards the mount face 402 and consequent generation of momentum energy. The absorption of energy from that momentum and the force of impact, particularly with repeated occurrences, may cause disturbingly loud impact sounds and may cause stress, marking, discolouration, or in some cases even cracking, of the casing 200.

The raised portion 210 is designed to cushion the impact caused by the magnetic coupling so that the mount face 402 and the recessed face 202 do not strike each other in flush contact at full force. The raised portion 210 may be formed from the same plastic as the casing 200. As described, the raised portion 210 may include a plurality of raised dimples, ridges, symbols, alphanumeric characters, or other glyphs. The lateral thickness of individual parts of the raised portion 210, e.g. the individual dimples, ridges, lines, curves, etc., may be selected to be sufficiently thin that the plastic forming those parts at least partly deforms under impact of the mount face 402 due to the magnetic coupling forces. The deformation of the raised portion 210 absorbs and dissipates at least some of the impact momentum, thereby reducing the momentum energy absorbed by the rest of the recessed face 202. Based on the plastic used in forming the raised portion and the maximum impact, the deformation may be temporary. That is, once the computing device 100 is removed from the mount face 402, the raised portion 210 may return to its pre-deformation shape. In some cases, the deformation occurs temporarily due to the momentary absorption of momentum energy, but the raised portion 210 returns to its pre-deformation shape even while the computing device 100 is mounted to the mount face 402 and is still subject to the continuing magnetic attraction force between the corresponding magnets in the computing device 100 and mount face 402.

The raised portion 210 may be centered in the recessed face 202 in some implementations. The raised portion 210 may be offset from the center of the recessed face 202 in some implementations. The raised portion 210 in the example shown in FIG. 3 is positioned in alignment with a vertical centerline of the recessed portion 202 but offset from a horizontal centerline of the recessed portion 202. The raised portion 210 may include more than one raised portion located in different areas of the recessed face 202. The more than one raised portion may be positioned symmetrically on the recessed face 202 or asymmetrically.

In some instances, the raised portion 210 is configured to communicate information in addition to its function in absorbing momentum. For example, the raised portion 201 may form alphanumeric characters and/or symbols. The raised portion may provide manufacturing data, electrical certification data, product model number information, trademark information, or other such product data.

Advantageously, the raised portion 210 may further serve to disguise an injection molding gate mark or vestige. Injection molding of plastic parts, such as the casing 200, typically involves injection of fluid resin into a cavity through a gate. The point where the gate meets the cavity typically results, or can often result, in a small vestige or raised residue point on the molded part. This vestige may be manually trimmed from the part in some cases. In some implementations of the present application, injection molding of the casing 200 may be designed with a mold that features a gate point within the raised portion 210 so that any vestige is formed as part of the raised portion 210, thereby avoiding the need to trim the vestige from the finished part.

In some implementations, an outer sidewall around the mount face 402 and the inner recessed sidewall 206 may include cooperating releasable mechanical latches or locking mechanisms for physically retaining the computing device 100 in place when mounted to the device mount 102 and to prevent inadvertent detachment if the computing device 100 is bumped, knocked or otherwise struck accidentally. A release button or latch on either the device mount 102 or the computing device 100 may be provided to release the mechanical latches when the computing device 100 is to be removed from the device mount 102.

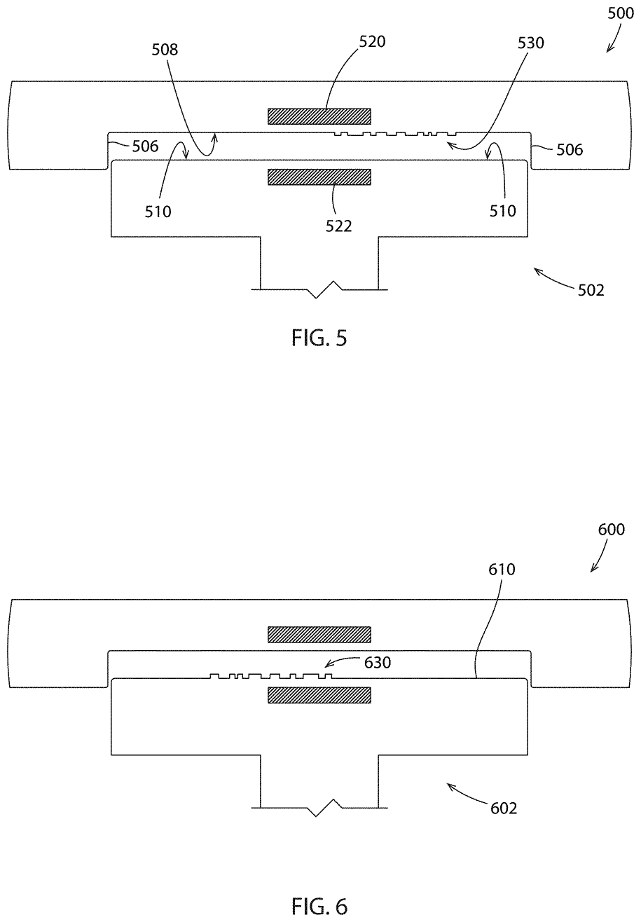

Reference is now made to FIG. 5, which shows a cross-sectional view of one example embodiment of a computing device 500 and a mount end 502. The computing device 500 includes casing 504 with a recessed portion on its backside defined by a recessed sidewall 506 and a recessed face 508. The mount end 502 includes a mount face 510 sized to fit within the recessed portion and intended to contact the recessed face 508 when the computing device 500 is placed on the device mount 502.

The computing device 500 includes a first magnet 520 beneath its casing 504. In this example the computing device 500 is shown with a single magnet, namely, the first magnet 520, but it will be appreciated that the first magnet 520 may include multiple magnets that may be positioned together or spaced apart. The device mount 502 includes a second magnet 522 beneath the mount face 510. The second magnet 522 may be a single magnet or may be multiple magnets that may be positioned in close proximity or spaced apart. The first magnet 520 may be one or more permanent magnets in some cases. The second magnet 522 may be one or more permanent magnets in some cases. The second magnet 522 may include one or more electromagnets. The first magnet 520 may include one or more electromagnets. Electromagnets may be suitable/more suitable for the device mount 502 in some implementations if the device mount 502 has a connection to a power source. In some implementations, one or other of the device mount 502 or the computing device 500 may include one or more proximity sensors configured to sense whether an object is sufficiently close to the mount face 510 and/or recessed face 508, as the case may be, to trigger circuitry to cause the electromagnet to be turned on, thereby only generating the electromagnetic field when an object is in close proximity.

The first magnet 520 and second magnet 522 may be positioned within the computing device 500 and device mount 502, respectively, such that they are approximately aligned across from each other when the computing device 500 is mounted to the device mount 502.

The cross-section in this example passes through a raised portion 530 of the recessed face 508. The raised portion 530 in this example is shown as a plurality of projections or nubs projecting outwards from the horizontal plane in which the recessed face 508 is situated between the recessed sidewalls 506.

If the computing device 500 is brought into contact with the device mount 502 when the recessed face 508 and the mount face 510 are parallel, then the raised portion 530 will be the first point of contact between them, and will absorb the bulk of the momentum energy. It will be appreciated that in many instances, the computing device 500 and device mount 502 are slightly angled with respect to each other when they first come into contact, such that an edge or corner of the mount face 500 may be the first point of contact with the recessed face 508. While there will be an impact force imparted at the point or edge of first contact, the momentum energy of the computing device 500 under the influence of the magnetic coupling will cause the point or edge to act as a pivot point torquing the computing device 500 and causing its recessed face 508 to snap closed against the mount face 510 and, in particular, causing the raised portion 530 to be sandwiched against the mount face 510.

If the raised portion 530 is too unmalleable or unyielding, it may not cushion the impact and may instead serve as a further pivot point causing the computing device 500 to rock on that pivot point at least temporarily. This may be countered in part by ensuring that the raised portion 530 is of a sufficiently malleable material and has a sufficiently thin geometry that it flexes to cushion and dissipate the momentum energy of the computing device 500. The may further be countered by providing for a sufficiently large raised portion 530 laterally, or by providing for multiple spaced apart raised portions 530 on the recessed face 508, in some implementations.

Reference is now made to FIG. 6, which shows a cross-sectional view of another example embodiment of a computing device 600 and a mount end 602. In this example, a raised portion 630 is provided on a mount face 610 of the mount end 602. Although many of the example embodiments shown and described herein provide for one or more raised portions on the recessed face of the computing device, a raised portion serving the same impact cushioning function may be provided for on the mount face in some implementations. The raised portion 630 in this example is provided instead of a raised portion on the computing device 600. In some implementations, raised portions may be provided for on both the recessed face of the computing device and the mount face of the device mount.

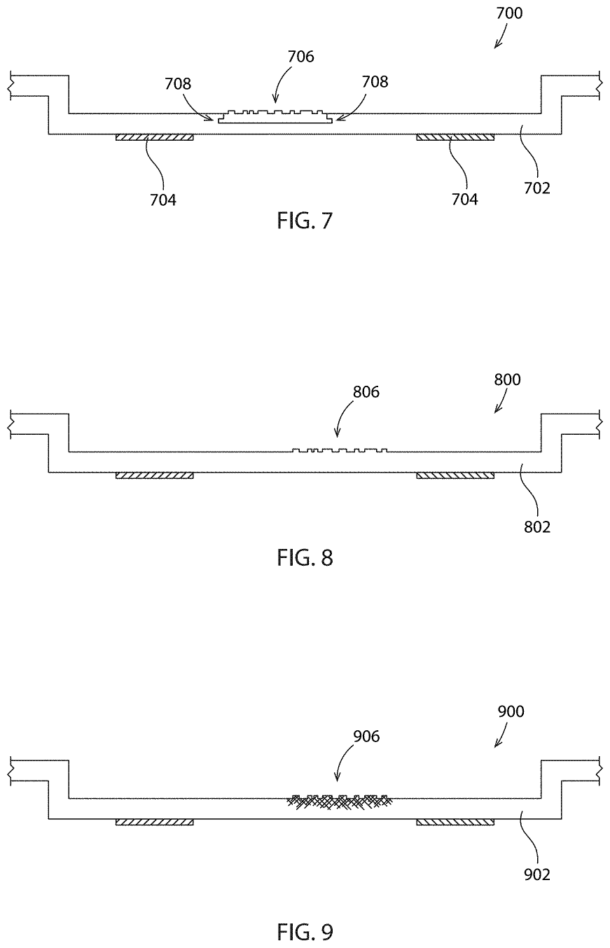

Reference will now be made to FIG. 7, which shows a cross-sectional view of a portion of a casing 702 of a computing device 700. The portion depicted is a cross-section of the recessed face in the backside of the casing 702.

In this example, the computing device 700 includes two permanent magnets 704 disposed behind the casing 702, and arranged symmetrically with regard to a centerline of the recessed face. Other implementations may include fewer or more magnets, and may have them arranged symmetrically or asymmetrically.

The casing 702 in this example is formed by way of injection molding using a suitable thermoplastic resin. The thermoplastic resin may be any suitable resin for forming the casing of an electronic device. The thermoplastic resin may be non-conducting and may be sufficiently rigid and resistant to scratching and discolouration to render it suitable for use in serving as a housing for a computing device. Example thermoplastic resins in some implementations may include a polycarbonate resin. In some cases, polyethylene or polypropylene may be used. Other suitable resins will be appreciated by those skilled in the art of injection molding.

In this example, a raised portion 706 is provided for that includes a plurality of projections above the flat outer surface of the recessed portion of the casing 702. The projections may be dimples, ridges, shapes, alphanumeric characters, or other symbols.

In this case, the raised portion 706 is formed from a different resin than the resin used in forming the casing 702. The raised portion 706 may be formed using a resin having more malleable or elastic properties in its finished state. In this example, the raised portion 706 is formed after injection molding of the casing 702 in a dual shot or double-shot injection. The raised portion 706 is formed after solidification of the casing 702 and the raised portion 706 and casing 702 are formed so as to be mechanically bonded after injection molding of the raised portion 706. In this example illustration, the mechanical bond is illustrated as lateral flanges 708 projecting from the raised portion 706 in the body of the casing 702, although this is merely an illustrative example. Any suitable mechanical locking or linking structure may be employed to ensure that the raised portion 706 is secured in place and attached to the casing 702 after injection molding.

FIG. 8 shows a cross-sectional view of another example of a portion of a casing 802 of a computing device 800. The portion depicted is a cross-section of the recessed face in the backside of the casing 802.

The casing 802 in this example is formed by way of injection molding using a suitable thermoplastic resin. The thermoplastic resin may be any suitable resin for forming the casing of an electronic device. The thermoplastic resin may be non-conducting and may be sufficiently rigid and resistant to scratching and discolouration to render it suitable for use in serving as a housing for a computing device. Example thermoplastic resins in some implementations may include a polycarbonate resin. In some cases, polyethylene or polypropylene may be used. Other suitable resins will be appreciated by those skilled in the art of injection molding.

In this example, a raised portion 806 is provided for that includes a plurality of projections above the flat outer surface of the recessed portion of the casing 802. The projections may be dimples, ridges, shapes, alphanumeric characters, or other symbols.

In this case, the raised portion 806 is formed from the same resin as the resin used in forming the casing 802. The raised portion 806 in this example is a contiguous part of the casing 802 and formed in the same injection molding operation as used to form the casing 802. Although the raised portion 806 is constructed from the same resin as used to form the casing 802, the dimensions of the projections forming the raised portion may be selected, given the type of resin, to ensure the raised portion is sufficiently flexible to elastically deform so as to dissipate impact energy.

Reference is now made to FIG. 9, which shows a cross-sectional view of a further example of a portion of a casing 902 of a computing device 900. The portion depicted is a cross-section of the recessed face in the backside of the casing 902.

The casing 902 in this example is formed by way of injection molding using a suitable thermoplastic resin. The thermoplastic resin may be any suitable resin for forming the casing of an electronic device. The thermoplastic resin may be non-conducting and may be sufficiently rigid and resistant to scratching and discolouration to render it suitable for use in serving as a housing for a computing device. Example thermoplastic resins in some implementations may include a polycarbonate resin. In some cases, polyethylene or polypropylene may be used. Other suitable resins will be appreciated by those skilled in the art of injection molding having regard to the present disclosure.

In this example, a raised portion 906 is provided for that includes a plurality of projections above the flat outer surface of the recessed portion of the casing 902. The projections may be dimples, ridges, shapes, alphanumeric characters, or other symbols.

In this case, the raised portion 806 is formed from a different resin than the resin used in forming the casing 802. The raised portion 806 may be formed using a resin having more malleable or elastic properties in its finished state. In this example, the raised portion 806 may be formed after injection molding of the casing 802, prior to injection molding of the casing 802, or at the same time as injection molding of the casing 802. The resins are selected and are injected so as to promote chemical bonding of the resins in the region of the raised portion 706.

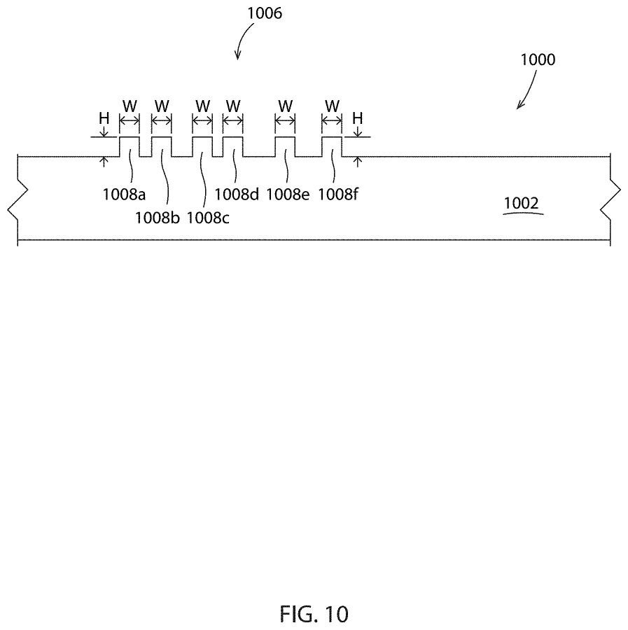

FIG. 10 shows a cross-sectional view of yet another example of a portion of a casing 1002 of a computing device 1000. The portion depicted is a cross-section of the recessed face in the backside of the casing 1002. The recessed face features a raised portion 1006 made up of a plurality of projections 1008 (shown as 1008a, 1008b, . . . , 1008f). Each projection has a width W and a height H in this example. The cross-section in this illustration cuts laterally across each of the projections 1008 cross-sectioning it. In some cases, the projections 1008 may be uniform dimples or similar symmetrical projections. In some cases, the projections may be elongate ridges, where the ridge has a width W and a height H. It will be appreciated that the length of the ridge is larger than W and in some instances much larger. In some cases, the projections may be more complex features, such as alphanumeric characters or other symbols, in which case the lines that make up the symbols or characters are generally of a width W and a height H.

The width W and the height H may be selected in view of the specific resin used in forming the raised portion 1006 such that when fully cured in finished form the projections 1008 exhibit elastic deformation under the impact forces and momentum energy transfers typical of mounting the computing device 1000 to a device mount under influence of a magnetic coupling. Projections that deform insufficiently may be designed to have a smaller width W so as to make them thinner. Projections that deform too easily and do not necessarily return to their pre-deformation shape may be made thicker by increasing the width W. In some cases the height H may be reduced to provide more resiliency to the projections 1008. A different resin may be selected to alter the elastic deformation characteristics of the projections 1008.

The strength of the magnetic coupling may further be adjusted to increase or decrease the likely impact forces and momentum energy. The strength of the magnetic coupling may be changed by changing the location of the magnet(s), particularly in the device mount since the ability to move magnets to different locations within the computing device may be severely constrained by the density of electronics in such devices.

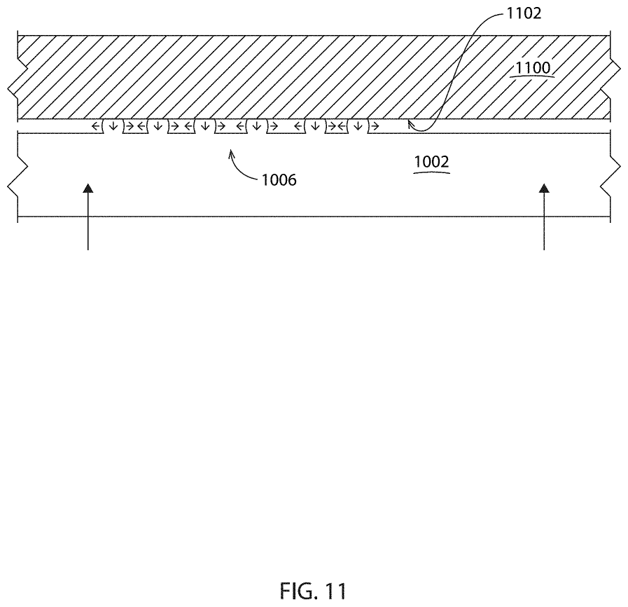

FIG. 11 illustrates the effect on the raised portion 1006 of initial contact with a device mount 1100 and, in particular, a mount face 1102 of the device mount 1100. The computing device 100 comes into contact with the mount face 1102 while under acceleration due to the magnetic forces acting upon it. When the projections 1008 strike the mount face 1102, the momentum energy is partly dissipated by temporary deformation of the projections 1008. That is the projections 1008 are to some degree compressed and to some degree urged outwards or “flattened” such that they temporarily take on a cross-sectional profile with a width wider than W and a height shorter than H. Once the momentum energy is expended in this deformation and elsewhere through transfer to the device mount, heat generation, etc., the elasticity of the resin allows the projections 1008 to rebound to their original shapes.

In each of the example embodiment discussed and described above, the computing device has a recessed portion on the back side of the device casing that is designed to receive the mount face of a design mount. It will be appreciated and understood that in alternative embodiments the design mount's mount face may have a recessed portion designed to receive the entirety of the computing device's back side, or may have a recessed portion designed to receive a corresponding projected face protruding from the device casing's back side. In yet another alternative embodiment, the device casing may have no recessed portion and may be designed to contact the mount face without either the device casing or the device mount having a recessed portion.

As noted, certain adaptations and modifications of the described embodiments can be made. Therefore, the above-discussed embodiments are considered to be illustrative and not restrictive.

1. A computing device comprising:
a device casing having a front side and a back side; and
one or more permanent magnets within the device casing and proximate the back side to secure the computing device to a mount face of a corresponding device mount by magnetic coupling between the one or more permanent magnets and one or more corresponding magnets in the device mount,
wherein the back side of the device casing includes a recessed portion having a recessed face to receive the mount face of the corresponding device mount in contact with the recessed face, and wherein the recessed face is formed from a thermoplastic resin and includes a plurality of raised portions, the raised portions projecting above the recessed face and having a thickness sufficiently small that the raised portions deform under contact with the mount face due to force of the magnetic coupling.

2. The computing device of claim 1, wherein the computing device further includes a device screen on the front side of the device casing.

3. The computing device of claim 1, wherein the plurality of raised portions form alphanumeric characters or related symbols as at least part of an information label.

4. The computing device of claim 1, wherein the plurality of raised portions are formed from a selected resin and formed to have a height above the recessed face and the thickness to elastically deform under an impact force caused by the magnetic coupling to the mount face.

5. The computing device of claim 4, wherein the plurality of raised portions return to an original shape after absorbing the impact force.

6. The computing device of claim 1, wherein at least one of the one or more permanent magnets is disposed at least partly below the plurality of raised portions.

7. The computing device of claim 6, wherein said at least one of the one or more permanent magnets is disposed to be directly opposite one of the corresponding magnets in the device mount when the computing device is on the device mount.

8. The computing device of claim 1, wherein the one or more permanent magnets are symmetrically disposed relative to at least a center line of the recessed face.

9. The computing device of claim 8, wherein the raised portions are symmetrically disposed relative to at least the center line.

10. The computing device of claim 1, further comprising a communications port having a plurality of contact points located within the recessed face for electrical connection to a corresponding communications port within the mount face of the device mount.

11. The computing device of claim 1, wherein the device casing is formed from a first thermoplastic resin and the raised portions are formed from a second thermoplastic resin.

12. The computing device of claim 11, wherein the first thermoplastic resin and the second thermoplastic resin are the same.

13. The computing device of claim 12, wherein the first thermoplastic resin and the second thermoplastic resin are different.

14. The computing device of claim 13, wherein the first thermoplastic resin and the second thermoplastic resin are different in at least one of resin type, additives, or colour.

15. A device mount for a computing device having a device casing with a back side, the device mount comprising:
a mounting arm having a mount end formed with a mount face sized to fit within a recessed portion of the back side of the device casing in contact with a recessed face of the back side of the device casing; and
one or more magnets within the mount end proximate the mount face to secure the computing device to the mount face by magnetic coupling with one or more corresponding permanent magnets in the computing device,
wherein the mount face is formed from a thermoplastic resin and includes a plurality of raised portions, the raised portions projecting above the mount face and having a thickness sufficiently small that the raised portions deform under contact with the recessed face due to force of the magnetic coupling.

16. The device mount of claim 15, wherein the mount face is formed from a first thermoplastic resin and the raised portions are formed from a second thermoplastic resin.

17. The device mount of claim 15, wherein the one or more magnets within the mount end are disposed at least partly beneath the plurality of raised portions.

18. The device mount of claim 15, wherein the plurality of raised portions are formed from a selected resin and formed to have a height above the recessed face and the thickness to elastically deform under an impact force caused by the magnetic coupling to the recessed face.

19. The device mount of claim 18, wherein the plurality of raised portions return to an original shape after absorbing the impact force.

20. A system comprising:
a computing device including a device casing having a front side and a back side; and
a device mount having a mounting arm having a mount end formed with a mount face sized to fit within a recessed portion of the back side of the device casing in contact with a recessed face of the back side of the device casing,
wherein the computing device includes one or more permanent magnets within the device casing and proximate the back side to secure the computing device to the mount face by magnetic coupling between the one or more permanent magnets and one or more corresponding magnets in the device mount, and
wherein one of the recessed face or the mount face is formed from a thermoplastic resin and includes a plurality of raised portions, the raised portions projecting above the recessed face or the mount face and having a thickness sufficiently small that the raised portions deform under contact between the mount face and the recessed face due to force of the magnetic coupling.
